(19) United States
(12) Patent Application Publication
(10) Pub. No.: US 2013/0116949 A1
(43) Pub. Date: May 9, 2013

(54) TESTING DEVICE FOR TESTING PRINTED CIRCUIT BOARD

(71) Applicant: Feng-Chi YANG, Tu-Cheng (TW)

(72) Inventor: Feng-Chi YANG, Tu-Cheng (TW)

(73) Assignee: HON HAI PRECISION INDUSTRY CO., LTD., Tu-Cheng (TW)

(21) Appl. No.: 13/491,619

(22) Filed: Jun. 8, 2012

(30) Foreign Application Priority Data
Nov. 3, 2011 (CN) 201110343041.7

(51) Int. Cl. G01R 31/304; G06F 19/00

(52) U.S. Cl. 702/58

(57) ABSTRACT

A testing device for testing a PCB is provided. The testing device includes an oscillograph, a number of switches, a control unit, and a processing unit. The oscillograph includes a first input channel. Each switch includes a first path terminal connected to one of the test points, a second path terminal connected to the first input channel, and a controlled terminal The control unit outputs a control signal to the controlled terminal of each of the switches to turn on and turn off the switches in sequence, within a period set by, and including, all the switches, then a periodic signal including signals at all the test points within of one single period is transmitted to the first input channel. The processing unit obtains the control signals and the overall periodic signal, and matches the signals at the test points from the periodic signal according to the control signals.

### 1. Technical Field

The present disclosure relates to testing devices, particularly, to testing device for testing a printed circuit board.

2. Description of Related Art

Printed circuit boards (PCBs) are used in electronic devices, such as mobile phones, digital cameras, and electronic book readers. In manufacturing, there is need to test whether each pin of electronic chips located on the PCB can output normal signals. The chips have a large number of pins, each pin is a test point of the PCB needing to be tested, when testing the pins of the chips of the PCB, it is necessary to use an oscillograph with a number of channels to capture the signals output by the pins. However, the oscillograph with a number of channels is very expensive, which increases the test cost. Furthermore, if the number of the pins is very large, the oscillograph with a certain number of channels may be too small to satisfy the requirement.

A testing device to overcome the described limitations is thus needed.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure.

Moreover, in the drawings, like reference numerals designate corresponding parts throughout the several views.

FIG. 1 is a block diagram of a testing device for testing a printed circuit board, in accordance with an exemplary embodiment.

FIG. 2 is schematic diagram of signals captured by an oscillograph of the testing device of FIG. 1, in accordance with an exemplary embodiment.

FIG. 3 is block diagram of a control unit of the testing device of FIG. 1, in accordance with an exemplary embodiment.

FIG. 4 is a schematic diagram of a sequence of signals produced by the control unit of the testing device of FIG. 1, in accordance with an exemplary embodiment.

### DETAILED DESCRIPTION

Embodiments of the present disclosure will be described, with reference to the accompanying drawings.

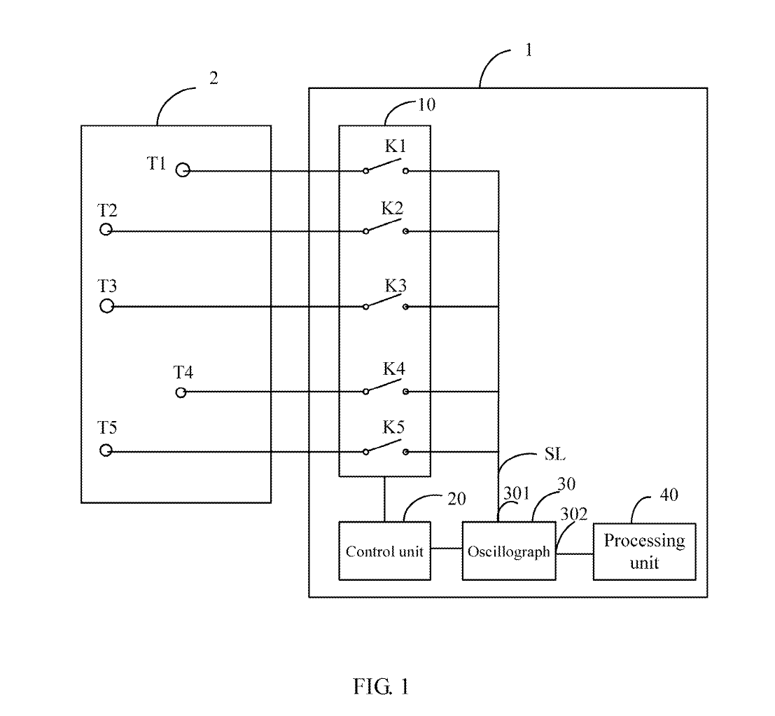

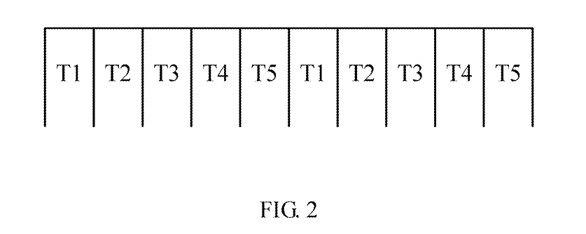

Referring to FIGS. 1 and 2 together, a testing device 1 for testing a PCB 2 is provided. The testing device 1 is used to test a number of test points of a PCB 2 by analyzing the signals output from the test points. The testing device 1 includes a switching unit 10, a control unit 20, an oscillograph 30, and a processing unit 40. The switching unit 10 includes a number of switches, the number of the switches is equal to the number of the test points required. For simplicity, there are 5 test points T1-T5 and 5 switches K1-K5 provided. Each one of the switches K1-K5 includes a first path terminal 101, a second path terminal 102, and a controlled terminal 103. Each first path terminal 101 of the switches K1-K5 is connected to a test point of the test points T1-T5. All of the second path terminals 102 of the switches K1-K5 are connected to an input channel 301 of the oscillograph 30 via a main signal line SL. The controlled terminals 103 of the switches K1-K5 are all connected to the control unit 20. The control unit 20 periodically outputs a control signal to the controlled terminal 103 of the switches K1/K2/K3/K4/K5 in sequence, to periodically turn on the switches K1-K5. In the embodiment, the switches K1-K5 are turned on only when receiving the control signal, therefore, there is only one switch being turned on at one time. That is, in one period, the control unit 20 outputs a first control signal to the first switch K1 and only turns on the first switch K1, and then outputs a second control signal to the second switch K2 and only turns on the second switch K2, etc.

When one switch is turned on, the signal at the test point connected to the switch can be transmitted to the input channel 301 via the main signal line SL. In each period, the switches K1-K5 are turned on in sequence, and the signals at the test points T1-T5 are transmitted to the input channel 301 of the oscillograph 30 via the main signal line SL in the same sequence. Therefore, the signals at the test points T1-T5 received by the oscillograph 30 constitutes a periodic signal and each period of the periodic signal includes signals of the all the test points T1-T5 in sequence as shown in FIG. 2. In the embodiment, each switch is turned on for a predetermined time period.

The oscillograph 30 is also connected to the control unit 20 and receives the control signals for controlling the switches K1-K5 from the control unit 20. The oscillograph 30 also includes an output channel 302 and is connected to the processing unit 40 via the output channel 302. The processing unit 40 receives the periodic signal and the control signals via the output channel 302 from the oscillograph 30, and restores the signal at each test point from the periodic signal according to the control signals. In detail, because the control signals turn on the switches K1-K5 sequentially one by one and turn the switches K1-K5 off sequentially in one period, then the control signals should correspond to the signals at the test point T1-T5 and match them one by one in one period, the processing unit 40 determines the signal of one of the test point T1-T5 of each period according to time of the corresponding control signal of each period produced by the control unit 20. Namely, the processing unit 40 determines the time of one control signal of each period produced by the control unit 20, and determines the time of the signal of the periodic signal corresponding to the time of the control signal is the signal of the same test point, then determines the signal of the test point of each period according to the time of the control signal.

For example, if the processing unit 40 determines that the first control signal is for controlling the switch K1 connected to the test point T1, then the processing unit 40 determines that the first control signal corresponds to any signal collected from the test point T1, thus the processing unit 40 determines that the time of the signal within the period is corresponding to signal at test point T1, if it is received at the correct time. The processing unit 40 then obtains the signal at the first test point at the same time as the first control signal produced by the control signal within each period. Therefore, the processing unit 40 obtains a series of signals at one test point, thus restoring the signals of each test point. The processing unit 40 also tests each one of the test points T1-T5 according to the series of signals taken.

In the embodiment, the signals of each of the test points T1-T5 received by the oscillograph 30 all have a time label, and the control signals of the processing unit 40 all have a time label.

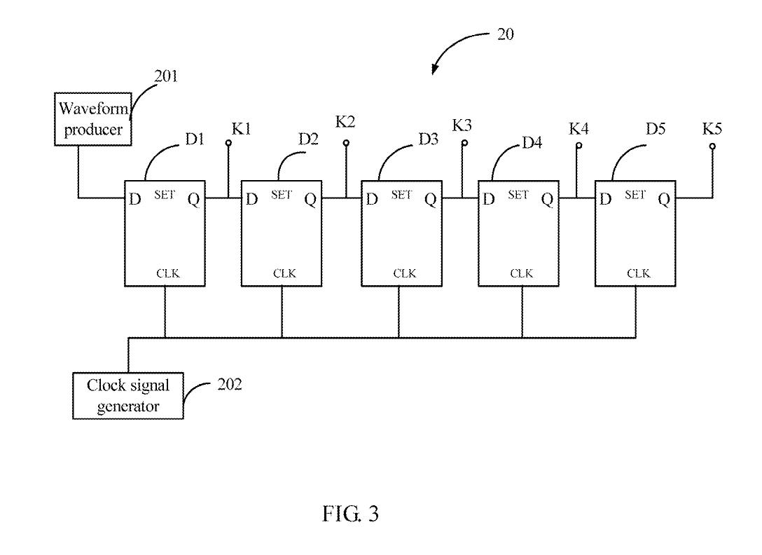

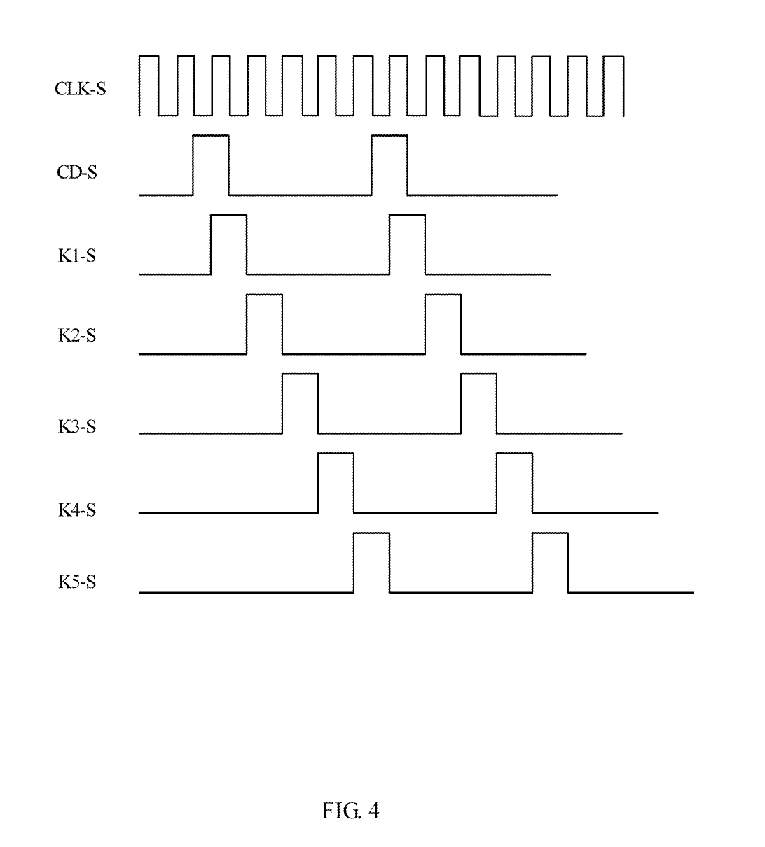

Referring to FIGS. 3 and 4 together, the control unit 20 includes a number of triggers D1-D5, a waveform producer 201, and a clock signal generator 202. Each one of the triggers D1-D5 includes an input terminal D, an output terminal Q, and a timing terminal CLK. The number of the triggers D1-D5 is also equal to the number of the test points T1-T5. The clock pulse generator 202 is connected to the timing terminals CLK of the triggers D1-D5 and is used to produce a clock signal CLK-S to the timing terminals CLK of the triggers D1-D5. As shown in FIG. 3, the triggers D1-D5 are connected in series, that is, the output terminal Q of each one of the triggers D1-D5 is connected to the input terminal D of an adjacent trigger connected in series therewith, and the triggers D1-D5 are connected in series from left to right. The output terminal Q of each trigger is connected to the controlled terminal 103 of each of the switches K1-K5. The waveform producer 201 is connected to the input terminal D of a first trigger (the leftmost trigger) of the triggers D1-D5, and is used to produce and transmit a waveform signal CD-S to the input terminal D of the first trigger of the triggers D1-D5.

As shown in FIG. 4, in the embodiment, the period time of the clock signal CLK-S output by the clock pulse generator 202 is the predetermined time period within which one of the switches K1-K5 is turned on. The period time of the waveform signal CD-S output by the waveform producer 201 equals N*T, where “N” is the number of the switches, and “T” is the predetermined time period when one of the switches K1-K5 is turned on. For example, if the total number of the switches K1-K5 is five, then the period time of the waveform signal CD-S is five times the predetermined time period.

In the embodiment, the triggers D1-D5 all are rising-edge-triggered, namely, the triggers D1-D5 become active when the clock signal CLK-S goes from low to high, and the high-to-low transition is ignored. The output terminals Q of the triggers D1-D5 output control signals K1-S, K2-S, K3-S, K4-S, and K5-S which are lagged behind the waveform signal CD-S output by the waveform producer 201. The control signal following the current control signal (K1-S, K2-S, K3-S, K4-S, or K5-S as the case may be) is delayed behind the current control signals for the predetermined time period.

In the embodiment, the waveform signal CD-S is high voltage when the clock signal CLK-S goes from low to high, then in the period of the waveform signal CD-S the control signals K1-S, K2-S, K3-S, K4-S, and K5-S respectively output by the output terminals Q of the triggers D1-D5 are at high voltage for the predetermined time period in sequence. In the embodiment, the switches K1-K5 are high voltage activated switches, thus the switches K1-K5 are turned on for the predetermined time period in sequence. Then, the signals at the test points T1-T5 are transmitted to the main signal line SL in sequence, and the signals at the test points T1-T5 received by the oscillograph 30 constitute the periodic signal, and one period of the periodic signal includes the signals at all the test points T1-T5 in sequence as shown in FIG. 2.

In the embodiment, the switches K1 -K5 are high voltage activated complementary metal oxide semiconductor (CMOS), N-channel metal oxide semiconductor field effect transistors (NMOSFET), or negative-positive-negative bipolar junction transistors (NPN BJT).

In the embodiment, the oscillograph 30 is also connected to the waveform producer 201 and the clock signal generator 202 and receives the waveform signal CD-S and the clock signal CLK-S from the waveform producer 201 and the clock signal generator 202 respectively. In the embodiment, the oscillograph 30 also includes a second input channel (not shown) and a third channel (not shown), and is connected to the waveform producer 201 and the clock signal generator 202 via the second input channel and the third channel respectively. The processing unit 40 receives the waveform signal CD-S and the clock signal CLK-S from the oscillograph 30, and determines the control signals output by control unit 20 according to the waveform signal CD-S and the clock signal CLK-S. As described above, the processing unit 40 determines the identity of the signal at one of the test points T1-T5 of each period according to the time order of the control signal of each period produced by the control unit 20, then obtains s series of signals at each one of the test points T1-T5. The processing unit 40 then tests each one of the test points T1-T5 according to the series of signals at the test point.

In another embodiment, the oscillograph 30 is connected to the output terminals Q of the triggers D1-D5 via at least one input channel (not shown) and receives the control signals from the triggers D1 -D5 directly. The processing unit 40 then obtains the control signals from the oscillograph 30 directly.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the present disclosure.

What is claimed is:

1. A testing device for testing a printed circuit board (PCB), the PCB having a plurality of test points, the testing device comprising;
an oscillograph comprising a first input channel;
a plurality of switches, wherein, each switch comprises a first path terminal, a second path terminal, and a controlled terminal, the first path terminals of the switches are respectively connected to a corresponding test point of the PCB, the second path terminals of the switches are all connected to the first input channel of the oscillograph via a main signal line;
a control unit connected to the controlled terminals of the switches, configured to output a control signal to the controlled terminals of the switches to turn on the switches in sequence and periodically, thereby the signals of the test points are transmitted to the first input channel of the oscillograph in sequence, wherein the signals of the test points constitute a periodic signal, and each period of the periodic signal comprise signals of the test points in sequence, and
a processing unit;
wherein, the oscillograph is further connected to the processing unit and the control unit, and configured to obtain the control signals from the control unit, the processing unit is further configured to obtain the control signals and the periodic signal from the oscillograph, and respectively restore the signals of the test points from the periodic signal according to the control signals, and then test each test point according to the restored signals of each test point.

2. The testing device for testing a PCB according to claim 1, wherein the processing unit determines the signals of each of the test points of each period according to time of the same control signal of each period produced by the control unit so as to respectively restore the signals of the test points from the periodic signal.

3. The testing device for testing a PCB according to claim 1, wherein the control unit comprises a plurality of triggers, a waveform producer, and a clock signal generator, each trigger comprises an input terminal, an output terminal, and a timing terminal, the clock pulse generator is connected to the timing terminals of the triggers and is configured to produce a clock signal to the timing terminals of the triggers, the output terminal of each trigger is connected to the input terminal of an adjacent trigger connected in series therewith, the output terminals of the triggers are respectively connected to the controlled terminals of the switches and is configured to output the control signal to the corresponding switch, the waveform producer is connected to the input terminal of a first trigger, and is configured to produce and transmit a waveform signal to the input terminal of the first trigger.

4. The testing device for testing a PCB according to claim 3, wherein the triggers all are rising edge-triggered, the switches are high voltage activated switches, the waveform signal is high voltage when the clock signal goes from low to high, wherein, in one period of the waveform signal, the output terminals of the triggers outputs the control signals at a high voltage in sequence, and then the switches are turned on in sequence.

5. The testing device for testing a PCB according to claim 4, wherein each switch is selected from the group consisting of a high voltage activated complementary metal oxide semiconductor, an N-channel metal oxide semiconductor field effect transistor, and a negative-positive-negative bipolar junction transistor.

6. The testing device for testing a PCB according to claim 3, wherein oscillograph further comprises a second input channel, a third input channel, and an output channel, the oscillograph connects to the waveform producer and obtains the waveform signal from the waveform producer via the second input channel, and connects to the clock signal generator and obtains the clock signal from the clock signal generator via the third channel, the processing unit obtains waveform signal and the clock signal from the oscillograph via the output channel and determines the control signals output by the control unit according to the waveform signal and the clock signal, and determine the time that each switch is turned on according to the control signals, and then respectively restores the signals of the test points from the periodic signal according to the control signals.

7. The testing device for testing a PCB according to claim 3, wherein the oscillograph further comprises at least one second input channel and an output channel, the oscillograph connects to the output terminals of the triggers via the at least one second input channel and obtains the controls signals from the output terminals of the triggers via the at least one second channel, the processing unit obtains the control signals from the oscillograph, and then respectively restores the signals of the test points from the periodic signal according to the control signals.

8. The testing device for testing a PCB according to claim 3, wherein the number of the switches is equal to the number of the test points, and is further equal to the number of the triggers.
